(19) United States
(12) Patent Application Publication
(10) Pub. No.: US 2003/0228850 A1
(43) Pub. Date: Dec. 11, 2003

(54) Transmit diversity apparatus for mobile communication system and method thereof

(75) Inventor: In-Tae Hwang, Gyunggi-Do (KR)

Correspondence Address: JONATHAN Y. KANG, ESQ., LEE & HONG P.C., 14th Floor, 801 S. Figueroa Street, Los Angeles, CA, 90017-5554, US

(73) Assignee: LG Electronics Inc.

(21) Appl. No.: 10/455,707

(22) Filed: Jun. 5, 2003

(30) Foreign Application Priority Data
Jun. 7, 2002 (KR) 2002-32074

(51) Int. Cl. H04B 1/00; H04B 7/00; H03C 7/02

(52) U.S. Cl. 455/101; 455/69; 370/209

(57) ABSTRACT

In a transmit diversity apparatus for a mobile communication system and a method thereof in accordance with the present invention, by varying forward channel coding and modulation methods according to a forward channel quality and transmitting a transmit symbol by a transmit diversity method such as a STTD and a STD, it is possible to improve forward channel transmit rate, obtain transmit diversity gain and improve error performance simultaneously.

### BACKGROUND OF THE INVENTION

1. Field of the Invention

The present invention relates to a transmit diversity apparatus for a mobile communication system and a method thereof.

2. Description of the Prior Art

In order to provide various multimedia services in a mobile communication system, improvement in data capacity and data transmission speed has been required. Accordingly, it has been urgent to develop a method for increasing a system capacity by using limited frequencies efficiently. In addition, generally greater capacity is required for a forward link in comparison with a backward link, and accordingly methods for increasing a capacity of a forward link have been presented.

An AMC (adaptive modulation and coding) scheme is for increasing a capacity of a forward link by using limited radio resources efficiently by estimating forward channel characteristics and varying coding and modulation methods according to variation of the forward channel characteristics.

FIG. 1 is a block diagram illustrating a general AMC (adaptive modulation and coding) apparatus.

The general AMC apparatus includes an AMC receiver 10 for estimating forward channel characteristics by using a reception signal received through a reception antenna 11, performing feedback of the estimated forward channel characteristics, demodulating and decoding the reception signal; and an AMC transmitter 20 for selecting a level of a MCS (modulation coding scheme) according to the feedback forward channel characteristics, coding and modulating transmission data according to the selected MCS level.

The AMC receiver 10 includes a channel estimator 12 for estimating forward channel characteristics by using the reception signal received through the reception antenna and transmitting the estimated forward channel characteristics; a demodulator 13 for detecting a demodulation method according to the forward channel characteristics estimated in the channel estimator 12 and demodulating the reception signal according to the demodulation method; a channel deinterleaver 14 for channel-deinterleaving the reception data demodulated in the demodulator 13; and a decoder 15 for decoding the reception data outputted from the channel deinterleaver 14.

The AMC transmitter 20 includes a MCS level selector 21 for selecting a MCS level according to the forward channel characteristics transmitted from the AMC receiver 10; an encoder 22 for encoding transmission data according to a pertinent coding rate of the MCS level; a channel interleaver 23 for channel-interleaving the transmission data encoded in the encoder 22 according to the MCS level; and a modulator 24 for modulating the transmission data outputted from the channel interleaver 23 according to a pertinent modulation method of the MCS level and transmitting it through the transmission antenna 25.

The AMC receiver 10 is included in a mobile station, and the AMC transmitter 20 is included in the base station.

The base station can perform the MCS level selection by receiving feedback of a SNR of a forward channel from the mobile station. OR, the mobile station can perform the MCS level selection according to a SNR of an estimated forward channel and transmits feedback of it to the base station.

First, a method for classifying MCS levels according to channel characteristics will be described.

FIG. 2A shows a method for classifying each MCS level according to a FER (frame error rate) and throughput about a SNR (signal-to-noise ratio).

For example, when a SNR of a channel is not less than 3.25 dB and not greater than 7.25 dB, a ⅔ coding rate-QPSK (quadrature phase shift keying) modulation method has a greater throughput in comparison with a ⅓ coding rate-QPSK modulation method. In addition, when a SNR of a channel is not less than 7.25 dB and not greater than 9.25 dB, a ⅔ coding rate-8PSK (phase shift keying) modulation method has a greater throughput in comparison with the ⅓ coding rate-QPSK modulation method. When a SNR of a channel is not less than 9.25 dB, a ⅔ coding rate-16QAM (quadrature amplitude modulation) method has a greater throughput in comparison with the ⅓ coding rate-QPSK modulation method.

Accordingly, when a SNR of a channel is not greater than 3.25 dB, the ⅓ coding rate-QPSK modulation method is selected. When a SNR of a channel is not less than 3.25 dB and not greater than 7.25 dB, the ⅔ coding rate-QPSK modulation method is selected. When a SNR of a channel is not less than 7.25 dB and not greater than 9.25 dB, the ⅔ coding rate-8PSK modulation method is selected. When a SNR of a channel is not less than 9.25 dB, the ⅔ coding rate-16QAM method is selected.

FIG. 2B is a table showing MCS levels with reference to FIG. 2A.

As depicted in FIG. 2B, a MCS level 1 shows the ⅓ coding rate-OPSK modulation method, a MCS level 2 shows the ⅔ coding rate-OPSK modulation method, a MCS level 3 shows the ⅔ coding rate-8PSK modulation method, and a MCS level 4 shows the ⅔ coding rate-16QAM method.

Hereinafter, the operation of the general ATM coding apparatus for the mobile communication system will be described.

The channel estimator 12 of the AMC receiver 10 of a mobile terminal estimates characteristics a forward channel by using a reception signal received through the reception antenna 11, and the estimated forward channel characteristics is feedback from the mobile terminal to the AMC transmitter 20 of the base station.

The demodulator 13 of the AMC receiver 10 of the mobile terminal detects a demodulation method according to the estimated forward channel characteristics and demodulates the reception signal according to the detected demodulation method. The demodulated reception signal is decoded through the channel deinterleaver 14 and the decoder 15.

When the forward channel characteristics are feedback from the AMC receiver 10 of the mobile terminal, the MCS level selector 22 of the AMC transmitter 20 of the base station selects an optimum MCS level according to the forward channel characteristics, and encoding, channel interleaving and modulation of the forward channel are performed according to the selected MCS level.

The encoder 22 of the AMC transmitter 20 encodes transmission data according to a pertinent coding rate of the MCS level, the channel interleaver 23 performs channel-interleaving of the encoded transmission data according to the MCS level, and the modulator 24 modulates the transmission data according to a pertinent modulation method of the MCS level and transmits the modulated transmission signal (transmission symbol) through the transmission antenna 25.

As described above, in the general ATM coding apparatus used for the mobile communication system, it is possible to improve transmission rate by varying modulation and coding scheme according to channel characteristics simply, however, it is impossible to improve error performance.

In the meantime, in a mobile communication system for supporting multimedia services, in order to increase forward link capacity, a method for increasing the number of antennas of a mobile terminal can be used. However, in the mobile terminal, because of power, size, weight, price limitations it is difficult to have a great number of antennas. On the other hand, the base station has less limitation in those aspects, a method for increasing the number of base station antennas can be selected as an alternative plan. As described above, methods for improving a communication capacity of a forward link by increasing complexity of the base station, namely, the transmitter, without increasing complexity of the mobile terminal, namely, the receiver have been researched, among them there is a transmit diversity scheme.

The transmit diversity scheme is for obtaining diversity gain by making multiple paths channels between a transmitter (base station) and a receiver (mobile terminal) by installing plural antennas at the transmitter (base station) side of a forward link.

The transmit diversity scheme can be divided into an open loop transmit diversity method and a closed loop transmit diversity method according to existence/non-existence of feedback data. The open loop transmit diversity method is for varying a transmit antenna at a certain time intervals by using plural transmission antennas without using feedback data in the transmitter side or using simple coding scheme, etc. The closed loop transmit diversity method is for performing transmission in the transmitter side (base station) by using information about a channel feedback from the receiver side (mobile terminal).

There is a STTD (space time transmit diversity) as the open loop transmit diversity method, and there is a STD (selective transmit diversity) as the closed transmit diversity method.

First, the STTD method will be described.

FIG. 3 shows an example of a transmitter using the STTD.

The transmitter using the STTD coding includes a STTD encoder 30 for transmitting the same transmit symbol through an orthogonal path without using feedback information in order to obtain a diversity gain.

The operation of the transmitter using the STTD coding will be described.

One slot consists of plural symbols, and the STTD encoder 30 encodes a whole slot. However, for descriptive convenience, STTD-encoding two symbol duration of one slot will be described descriptive convenience.

When S is a symbol, T is a symbol duration, Tc is a chip time and M is a spreading gain, there is a relation as Tc=T/M. Rₚᵢₗₒₜ is pilot information having the R-number of symbols, and N_{data} is data having the N-number of symbols.

When S₁ is inputted in a certain time T and S₂ is inputted in 2T, in the time T, the STTD encoder 30 outputs S₁ for a first antenna (Ant0) and outputs −S₂* as minus conjugate of S₂ for a second antenna (Ant1). In addition, in the time 2T, the STTD encoder 30 outputs S₂ for the first antenna (Ant0) and outputs S₁* as conjugate of S₁ for the second antenna (Ant1).

The transmitter respectively performs spreading and scrambling of the STTD-encoded symbols of the first and second antennas and transmits them through multiple channels.

Accordingly, the transmitter using the STTD coding transmits two transmit symbols (S₁, S₂) for the 2T time. By transmitting the same transmit symbols through orthogonal paths, it is possible to obtain a diversity gain.

The receiver the STTD decoding classifies-demodulates the symbol of each transmission antenna on time and space domains. For example, when two transmit symbols are STTD-coded and transmitted for the 2T time, the 2T time is required for STTD-decoding the two transmit symbols.

FIG. 4 is a graph showing a reception SNR (signal to noise) according to the STTD.

The receiver for receiving signals transmitted through the orthogonal paths through one reception antenna can stabilize a reception SNR although one channel is in a Null state.

Hereinafter, the STD method will be described.

FIG. 5 shows basic operations of the STD.

When a forward channel state is feedback by the receiver (mobile terminal), the transmitter (base station) selects a transmit antenna having an optimum forward channel state and transmits transmit data (transmit slot) through the selected transmit antenna. For example, when the feedback forward channel state indicates the first antenna (Ant0) is in the optimum state, the transmitter transmits a #0 transmit slot through the first antenna (Ant0), when the feedback forward channel state indicates the second antenna (Ant1) is in the optimum state, the transmitter transmits a #1 transmit slot through the second antenna (Ant1). By transmitting the transmit slot to the transmit antenna in a better state, the transmitter (base station) can obtain a diversity gain.

However, when a transmitter (base station) including two transmit antennas transmits transmit data by the STD method, it takes T time for transmitting one transmit data to an optimum transmit antenna, and it takes 2T time for transmitting two transmit data. In addition, a receiver (mobile terminal) using the STD method, it takes T time for demodulating one data, and it takes 2T time for demodulating two transmit data.

Accordingly, in the STD scheme, it is possible to improve error performance by obtaining a diversity gain, however, it is impossible to improve transmission rate greatly.

FIG. 6 is a graph showing a reception SNT according to the STD.

In a receiver using the STD, when there are the two transmit antennas (Ant0, Ant1), by receiving a signal from a transmit antenna having a better reception state, reception SNR can be stabilized.

FIG. 7 shows error performance according to the STTD and the STD.

The STD for receiving signals transmitted only through an optimum transmit antenna has a better reception SNR in comparison with the STTD for receiving signals simultaneously transmitted through plural transmit antennas through averaging. Regardless of the OPSK or the 8PSK, the STD has better error performance than that of the STTD.

As described above, in the STTD method and the STD method, it is possible to improve error performance by obtaining a diversity gain, however, it is impossible to improve transmission rate greatly.

### SUMMARY OF THE INVENTION

In order to solve the above-mentioned problem, it is an object of the present invention to provide a transmit diversity apparatus for a mobile communication system and a method thereof capable of improving transmission rate and error performance of a forward link for providing a high speed multimedia service in a mobile communication system.

It is another object of the present invention to provide a transmit diversity apparatus for a mobile communication system and a method thereof capable of improving transmission rate and error performance of a forward link by combining an ATM coding method with a transmit diversity method (STTD or STD).

In order to achieve the above-mentioned objects, a transmit diversity apparatus for a mobile communication system in accordance with the present invention includes a receiver which estimates a forward channel state by STTD-decoding a reception signal; and a transmitter which selects a MCS level according to the estimated forward channel state, codes and modulates transmit data of the forward channel according to the selected MCS level and STTD-codes the transmit data so as to be transmitted through paths orthogonal to each other.

In order to achieve the above-mentioned objects, a transmit diversity apparatus for a mobile communication system in accordance with the present invention includes a receiver which estimates a forward channel state by channel-compensating a reception signal, generates antenna selection information for selecting an optimum forward channel on the basis of the estimated forward channel state and feedbacks the estimated forward channel state information and antenna selection information; and a transmitter which selects a forward channel MCS level according to the feedback forward channel state information, codes and modulates forward channel transmit data according to the selected MCS level, selects a transmit antenna according to the antenna selection information and transmits the transmit data to the selected transmit antenna.

In order to achieve the above-mentioned objects, a transmit diversity method for a mobile communication system in accordance with the present invention includes estimating a forward channel state by decoding a reception signal received through one reception antenna by transmit antennas; selecting coding rate and modulation method of a forward channel according to the estimated forward channel state; coding and modulating a transmit data according to the selected coding rate and modulation method of the forward channel; and transmitting the transmit data through plural transmit antennas by a STTD or STD method.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a block diagram illustrating a general AMC (adaptive modulation and coding) apparatus;

FIG. 2A shows a method for classifying each MCS level according to a FER (frame error rate) and throughput about a SNR (signal-to-noise ratio);

FIG. 2B is a table showing MCS levels with reference to FIG. 2A;

FIG. 3 shows an example of a transmitter using the STTD;

FIG. 4 is a graph showing a reception SNR (signal to noise) according to the STTD;

FIG. 5 shows basic operations of the STD;

FIG. 6 is a graph showing a reception SNT according to the STD;

FIG. 7 shows error performance according to the STTD and the STD;

FIG. 8 is a block diagram illustrating a transmit diversity apparatus for a mobile communication system in accordance with an embodiment of the present invention;

FIG. 9 is a block diagram illustrating a transmit diversity apparatus for a mobile communication system in accordance with another embodiment of the present invention; and

FIG. 10 is a graph showing performance of a transmit diversity apparatus for a mobile communication system in accordance with the present invention.

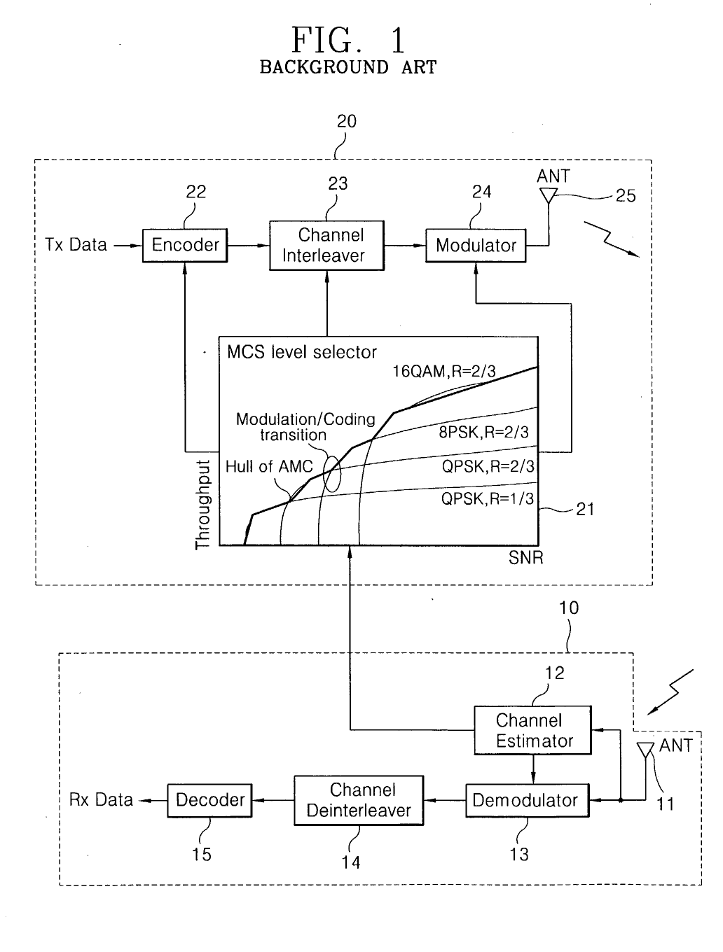

### DETAILED DESCRIPTION OF THE PREFERRED EMBODIMENT

Hereinafter, the preferred embodiment of the present invention will be described.

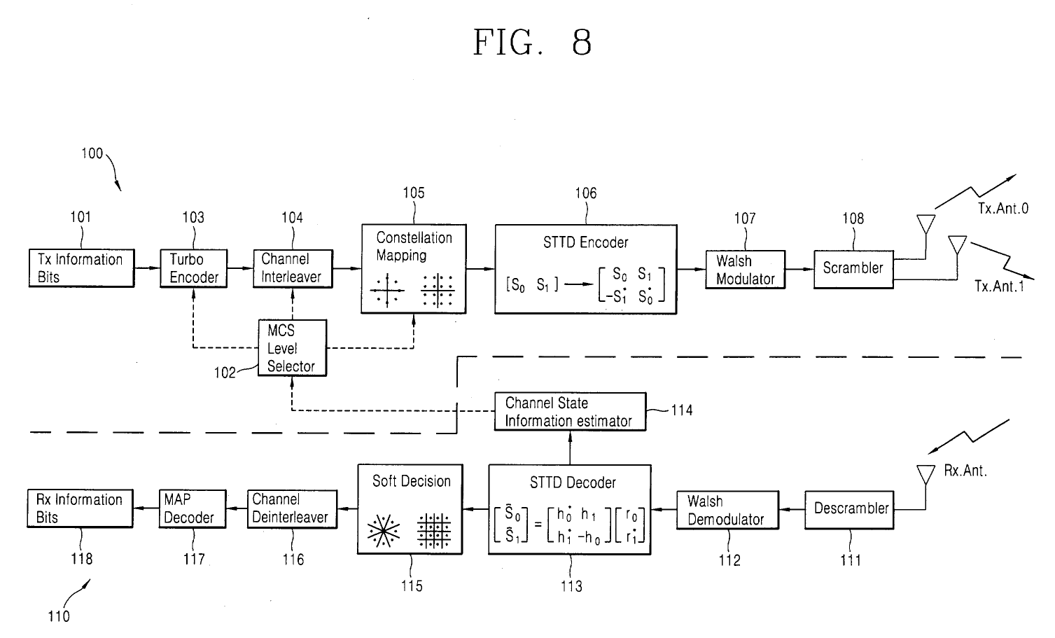

FIG. 8 is a block diagram illustrating a transmit diversity apparatus for a mobile communication system in accordance with an embodiment of the present invention.

The transmit diversity apparatus for the mobile communication system in accordance with the embodiment of the present invention includes a receiver 110 for estimating a forward channel state by STTD-decoding a reception signal; and a transmitter 100 for selecting a MCS level according to the estimated forward channel state, coding and modulating transmit data of the forward channel according to the selected MCS level and transmitting a transmit symbol to each transmit antenna through STTD-coding.

The receiver 110 is arranged in a mobile terminal, and the transmitter is arranged in a base station.

The receiver 110 includes a descrambler 111 for descrambling the reception symbol received through one reception antenna (Rx Ant); a walsh demodulator 112 for despreading the descrambled reception symbol through walsh demodulation; a STTD decoder 113 for performing STTD-decoding of the despread reception symbol; a channel state information estimator 114 for estimating a forward channel state by using the STTD-decoded reception symbol; a demodulator 115 for demodulating the STTD-decoded reception symbol by using soft decision; a channel deinterleaver 116 for channel-deinterleaving the demodulated reception bit data; and a MAP (maximum a posteriori) decoder 117 for outputting a reception information bit 118 by decoding the channel-deinterleaved bit data.

The STTD decoder 113 classifies the reception symbol transmitted through paths orthogonal to each other by each transmit antenna in temporal and spatial regions, demodulates it and performs averaging.

The transmitter 100 includes a MCS level selector 102 for selecting a MCS level according to the estimated forward channel state information; a turbo encoder 103 for turbo-coding a transmit information bit 101 according to the MCS level selected by the MCS level selector 102; a channel interleaver 104 for channel-interleaving the coded information bit according to the MCS level; a modulator 105 for modulating the channel-interleaved information bit according to the MCS level through constellation mapping; a STTD encoder 106 for STTD-coding the modulated transmit symbol; a walsh modulator 107 for spreading the STTD-coded transmit symbols of each transmit antenna through walsh modulation; and a scrambler 108 for scrambling the spread transmit symbols and transmitting them to each transmit antenna (Tx Ant0, Tx Ant1) simultaneously.

The STTD encoder 106 transmits the transmit symbol through two paths orthogonal to each other in temporal and spatial regions.

The MCS level selector 102 can be arranged in the transmitter 100 or the receiver 110, herein, arranging the MCS level selector 102 in the transmitter 110 will be described.

The operation of the transmit diversity apparatus for the mobile communication system in accordance with the embodiment of the present invention will be described.

The receiver 110 estimates a forward channel state by STTD-decoding the signal received through one reception antenna (Rx Ant) and performs feedback of the estimated forward channel state. The transmitter 100 selects a MCS level according to the feedback forward channel state, codes and modulates transmit data of the forward channel according to the selected MCS level, STTD-codes the transmit symbol so as to be transmitted through orthogonal paths in temporal and spatial regions and transmits it to each transmit antenna.

It will be described in more detail.

For example, when the transmitter 100 includes two transmit antennas (Tx Ant0, Tx Ant1) and the receiver 110 includes one reception antenna (Rx Ant), the reception symbol received through one reception antenna (Rx Ant) is transmitted to the STTD decoder 113 through the descrambler 111 and the walsh demodulator 112. The STTD decoder 113 classifies and demodulates the received reception symbol by each transmit antenna in temporal and spatial regions and performs averaging of symbols of each transmit antenna. Accordingly, although a forward channel by a random transmit antenna is in a null state, a reception SNR is stabilized, transmit diversity gain occurs, and error performance is improved.

The channel state information estimator 114 estimates a SNR of the forward channel by using the STTD-demodulated reception symbol, and the receiver 110 performs feedback of the estimated SNR of the forward channel.

The reception symbol outputted from the STTD decoder 113 of the receiver 110 sequentially passes the demodulator 115, the channel deinterleaver 116, the MAP decoder 117 and is outputted as the reception information bit format 118.

In the meantime, when the SNR of the forward channel is feedback from the receiver 110, the MCS level selector 102 of the transmitter 100 selects a MCS level according to the feedback forward channel SNR. Herein, the greater the SNR, the higher coding rate and the finer modulation method are selected. Accordingly, when a SNR is good, transmit rate can be improved.

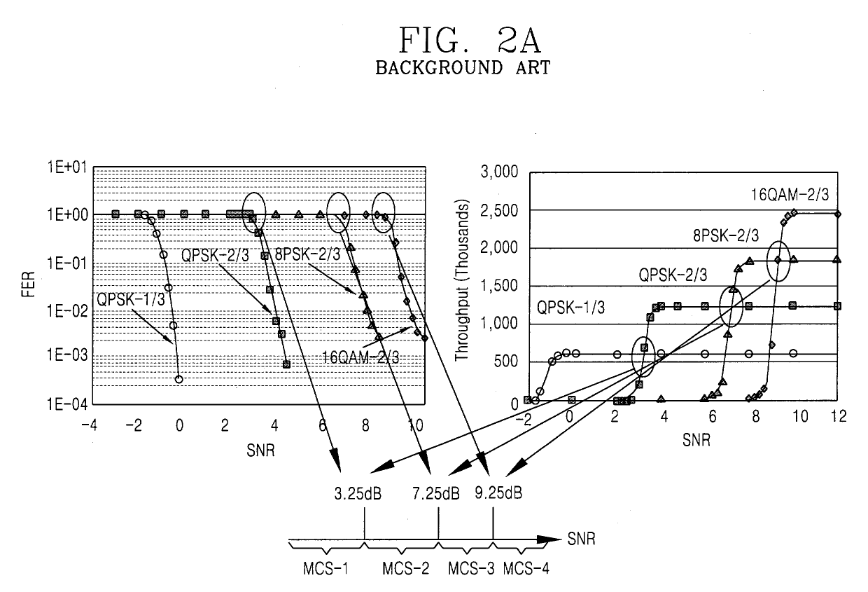

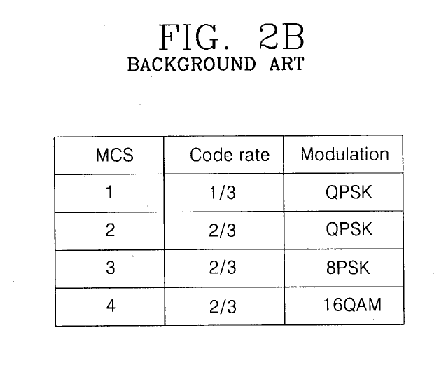

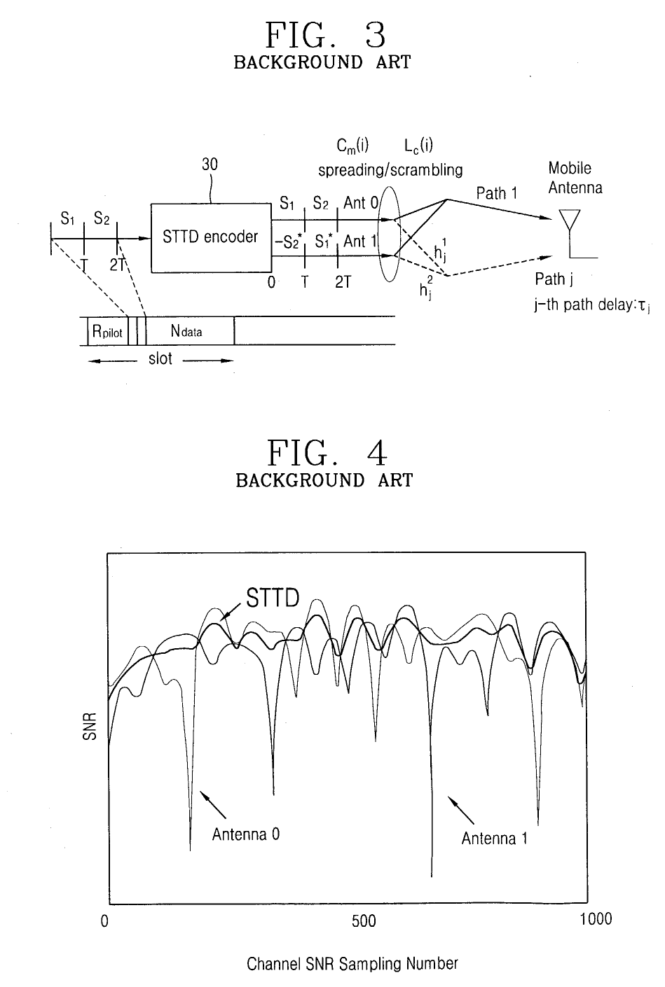

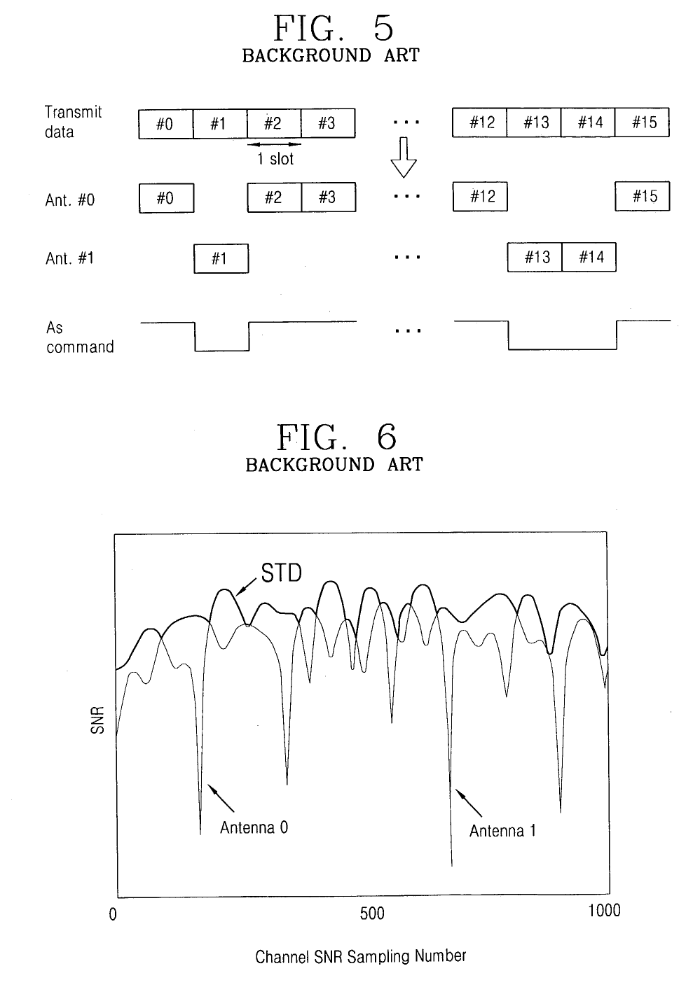

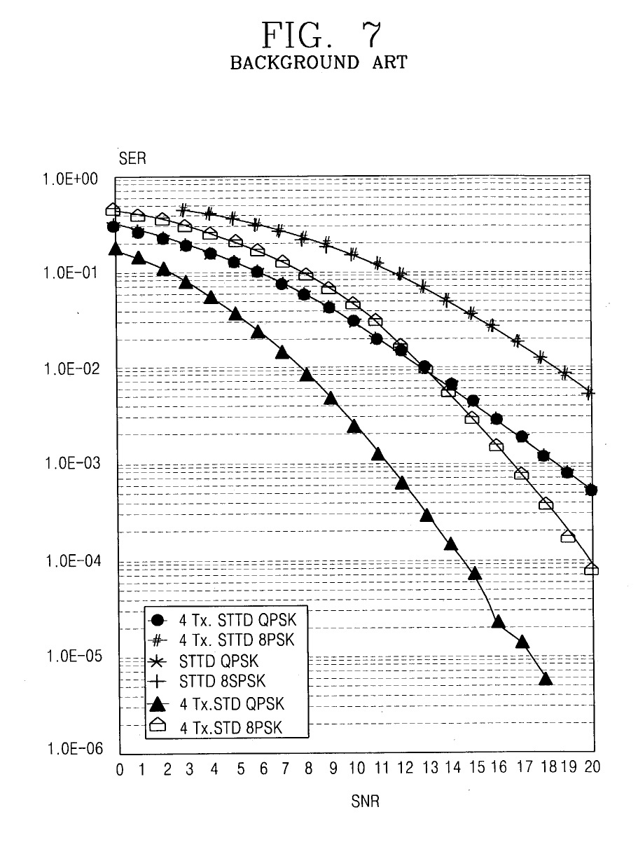

With reference to FIGS. 2A and 2B, in MCS level-selecting by the MCS level selector 102, when a forward channel SNR is greater than 3.25 dB and not greater than 7.25 dB, the MCS level selector 102 selects the ⅔ coding rate coding and the QPSK modulation method. When a forward channel SNR is greater than 9.25 dB, the MCS level selector 102 selects the ⅔ coding rate coding and the 16QAM modulation method.

The turbo encoder 103 of the transmitter 100 performs turbo-encoding of the transmit information bit 101 according to the selected MCS level coding rate, the channel interleaver 104 performs channel-interleaving according to the MCS level, and the modulator 105 modulates the transmit symbol according to the MCS level modulation method. For example, when the MCS level is a MCS level 2, turbo-encoding is performed according to the ⅔ coding rate, modulation is performed by the QPSK method.

The STTD encoder 106 performs the STTD coding of the adaptive-modulated transmit symbol so as to be transmitted through orthogonal two paths in temporal and spatial regions.

The walsh modulator 107 performs spreading of the STTD-coded first transmit antenna (Tx Ant0) data and second transmit antenna (Tx Ant1) data. The scrambler 108 performs scrambling of the spread STTD-coded first transmit antenna (Tx Ant0) data and second transmit antenna (Tx Ant1) data and transmits them to the first transmit antenna (Tx Ant0) and the second transmit antenna (Tx Ant1). Accordingly, one transmit symbol is transmitted through the orthogonal paths, namely, the first transmit antenna (Tx Ant0) and the second transmit antenna (Tx Ant1).

In the transmit diversity apparatus in accordance with the present invention, by varying coding and modulation method according to a forward channel SNR and transmitting transmit symbols adaptively coded-modulated according to a forward channel SNR through two orthogonal paths, the greater the forward channel SNR, transmit rate of a forward channel can be improved, transmit diversity gain can be obtained, and accordingly it is possible to improve transmit performance and error performance simultaneously.

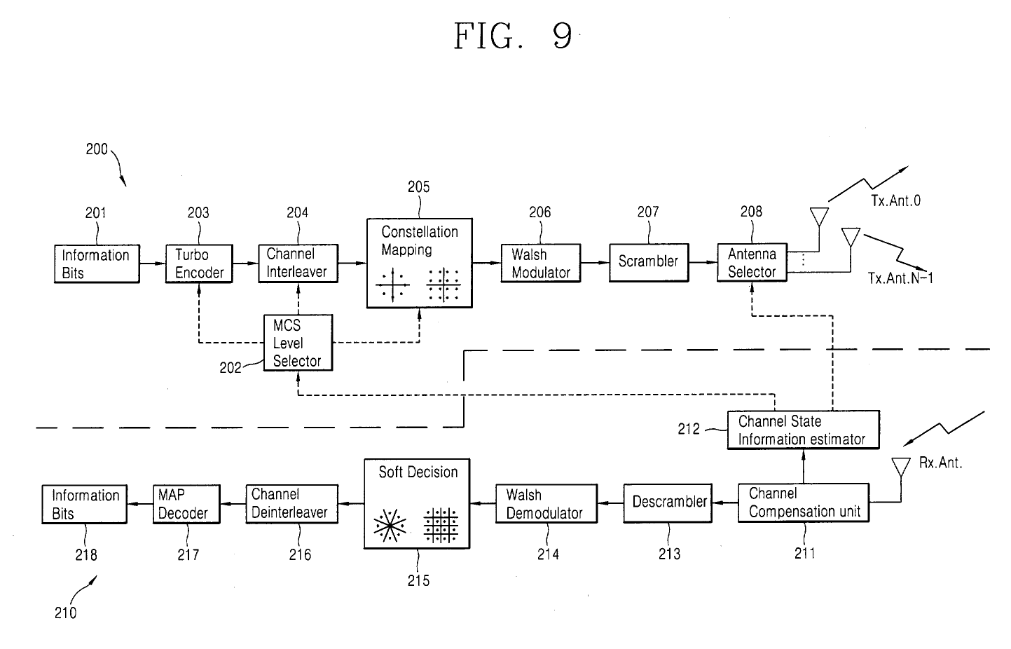

FIG. 9 is a block diagram illustrating a transmit diversity apparatus for a mobile communication system in accordance with another embodiment of the present invention.

A transmit diversity apparatus for a mobile communication system in accordance with another embodiment of the present invention includes a receiver 210 for estimating a forward channel state by channel-compensating a reception signal and performing feedback of the estimated forward channel state information and antenna selection information for transmit antenna selection; and a transmitter 200 for selecting a forward channel MCS level according to the feedback forward channel state information, coding and modulating forward channel transmit data according to the selected MCS level and transmitting the transmit data to a transmit antenna selected according to the antenna selection information.

The receiver 210 is arranged in a mobile terminal, and the transmitter 200 is arranged in a base station.

The receiver 210 includes a channel compensator 211 for channel-compensating a reception symbol received through one reception antenna (Rx Ant); a channel state information estimator 212 for estimating a forward channel state by using the channel-compensated reception symbol and generating antenna selection information for reception antenna selection on the basis of the estimated forward channel state; a descrambler 213 for descrambling the channel-compensated reception symbol; a walsh demodulator 215 for despreading the descrambled reception symbol through walsh demodulation; a demodulator 215 for demodulating the despread reception symbol through soft decision; a channel deinterleaver 216 for channel-deinterleaving the demodulated reception bit data; and a MAP decoder 217 for outputting a reception information bit 218 by decoding the channel-deinterleaved bit data.

The transmitter 200 includes a MCS level selector 202 for selecting a forward channel MCS level according to the forward channel state feedback by the receiver 210; a turbo encoder 203 for turbo-coding a transmit information bit 201 according to the selected MCS level; a channel interleaver 204 for channel-interleaving the coded information bit according to the MCS level; a modulator 205 for modulating the channel-interleaved information bit according to the MCS level through constellation mapping; a walsh modulator 206 for spreading the modulated transmit symbol by using walsh function; a scrambler 207 for scrambling the spread transmit symbol; and an antenna selector 208 for selecting an optimum transmit antenna among plural transmit antennas (Tx Ant0˜Tx Ant(N−1)) according to the antenna selection information feedback by the receiver 210 and transmitting the scrambled transmit symbol to the selected transmit antenna.

The MCS level selector 202 can be arranged in the transmitter 200 or the receiver 210, herein, arranging the MCS level selector 102 in the transmitter 110 will be described.

The operation of the transmit diversity apparatus for the mobile communication system in accordance with the another embodiment of the present invention will be described.

The receiver 210 estimates a forward channel SNR by channel-compensating a reception symbol received through one reception antenna (Rx Ant), generates antenna selection information for transmit antenna selection on the basis of the estimated forward channel SNR and performs feedback of the estimated forward channel SNR and antenna selection information.

The transmitter 200 selects a forward channel MCS level according to the feedback forward channel SNR, codes and modulates forward channel transmit data according to the selected MCS level, selects an optimum SNR transmit antenna according to the feedback antenna selection information and transmits transmit data to the selected transmit antenna.

It will be described in detail.

The channel compensator 211 of the receiver 210 channel-compensates a reception symbol received through one reception antenna (Rx Ant). The channel state information estimator 212 estimates a forward channel SNR by using the channel-compensated reception symbol and generates antenna selection information for selecting an optimum forward channel (transmit antenna) among forward channels in an idle state logically connected to a forward channel having transmit data. The receiver 210 performs feedback of the estimated forward channel SNR and antenna selection information.

The reception symbol outputted from the channel compensator 211 of the receiver 210 is demodulated in the demodulator 215 after passing the scrambler 213 and the walsh demodulator 214. The demodulated reception bit data is outputted as reception information bit format 218 by passing the channel deinterleaver 216 and the MAP decoder 217 sequentially.

In the meantime, the MCS level selector selects a MCS level by using the forward channel SNR feedback from the receiver 210. Herein, the greater the SNR, the higher coding rate and the finer modulation method are selected. Accordingly, the greater the SNR, transmit rate can be improved. The MCS level selection method of the MCS level selector 202 is the same with that of the MCS level selector 102, and accordingly detailed description will be abridged.

The turbo encoder 203 of the transmitter 200 performs turbo-encoding of the transmit information bit 201 according to the selected MCS level coding rate, the channel interleaver 303 performs channel-interleaving according to the selected MCS level, and the modulator 205 modulates the transmit symbol according to the MCS level modulation method. For example, when the feedback MCS level is MCS level 2, turbo-encoding is performed according to the ⅔ coding rate, and modulation is performed according to the QPSK method.

The walsh modulator 107 performs spreading of the modulated transmit symbol by using walsh function, and the scrambler 207 performs scrambling of the spread transmit symbol.

The antenna selector 208 selects an optimum SNR transmit antenna on the basis of the feedback antenna selection information and transmits the scrambled transmit symbol to the selected transmit antenna.

As described above, in the transmit diversity apparatus in accordance with the present invention, by varying coding and modulation method according to a forward channel SNR and transmitting transmit symbols adaptively coded-modulated according to a forward channel SNR to an optimum transmit antenna, the greater the forward channel SNR, transmit rate of a forward channel can be improved, transmit diversity gain can be obtained, and accordingly it is possible to improve transmit performance and error performance simultaneously.

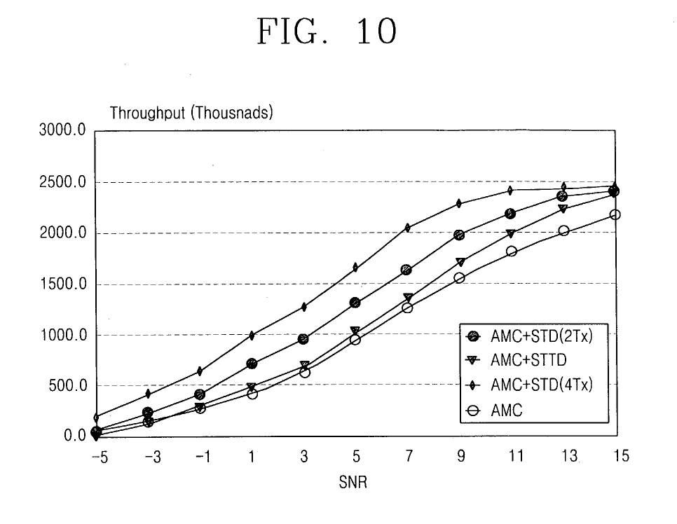

FIG. 10 is a graph showing performance of a transmit diversity apparatus for a mobile communication system in accordance with the present invention. When the AMC is combined with the STTD, it shows better throughput in comparison with the AMC. When the AMC is combined with the STD, it shows better throughput in comparison with the combination of the AMC and the STTD. In combination of the AMC and the STD, it shows better throughput in having four transmit antennas in comparison with a case having two transmit antennas.

As described above, in the transmit diversity apparatus for the mobile communication system and the method thereof in accordance with the present invention, by varying forward channel coding and modulation methods according to a forward channel quality and transmitting a transmit symbol by a transmit diversity method such as the STTD and the STD, it is possible to improve forward channel transmit rate, obtain transmit diversity gain and improve error performance simultaneously.

What is claimed is:

1. A transmit diversity apparatus for a mobile communication system, comprising:
a receiver which estimates a forward channel state by STTD-decoding a reception signal; and
a transmitter which selects a MCS level according to the estimated forward channel state, codes and modulates transmit data of the forward channel according to the selected MCS level and STTD-codes the transmit data so as to be transmitted through paths orthogonal to each other.

2. The apparatus of claim 1, wherein the receiver includes:
a STTD decoder for classifying a reception symbol received through one reception antenna by transmit antennas in temporal and spatial regions and STTD-decoding it; and
a channel state information estimator for estimating a forward channel state by using the STTD-decoded reception symbol.

3. The apparatus of claim 2, wherein the receiver further includes:
a descrambler for descrambling the reception symbol received through the one reception antenna;
a walsh demodulator for despreading the descrambled reception symbol through walsh demodulation and outputting it to the STTD decoder;
a demodulator for demodulating the STTD-decoded reception symbol by using soft decision;
a channel deinterleaver for channel-deinterleaving the demodulated reception bit data; and
a MAP (maximum a posteriori) decoder for outputting a reception information bit by decoding the channel-deinterleaved bit data.

4. The apparatus of claim 1, wherein the transmitter includes:
a MCS level selector for selecting a MCS level according to the forward channel state information estimated by the receiver;
a turbo encoder for turbo-coding a transmit information bit according to the selected MCS level;
a channel interleaver for channel-interleaving the coded information bit according to the selected MCS level;
a modulator for modulating the channel-interleaved information bit according to the MCS level through constellation mapping; and
a STTD encoder for STTD-coding the transmit symbol so as to be transmitted through paths orthogonal to each other in temporal and spatial regions.

5. The apparatus of claim 4, wherein the transmitter further includes:
a walsh modulator for spreading the STTD-coded transmit symbols of each transmit antenna through walsh modulation; and
a scrambler for scrambling the spread transmit symbols and transmitting them to each transmit antenna.

6. The apparatus of claim 4, wherein the MCS level selector can be included in not the transmitter but the receiver.

7. The apparatus of claim 1, wherein the receiver is arranged in a mobile terminal, and the transmitter is arranged in a base station.

8. A transmit diversity apparatus for a mobile communication system, comprising:
a receiver which estimates a forward channel state by channel-compensating a reception signal, generates antenna selection information for selecting an optimum forward channel on the basis of the estimated forward channel state and feedbacks the estimated forward channel state information and antenna selection information; and
a transmitter which selects a forward channel MCS level according to the feedback forward channel state information, codes and modulates forward channel transmit data according to the selected MCS level, selects a transmit antenna according to the antenna selection information and transmits the transmit data to the selected transmit antenna.

9. The apparatus of claim 8, wherein the receiver includes:
a channel compensator for channel-compensating a reception symbol received through one reception antenna; and
a channel state information estimator for estimating a forward channel state by using the channel-compensated reception symbol and generating antenna selection information for selecting an optimum forward channel.

10. The apparatus of claim 9, wherein the receiver further includes:
a descrambler for descrambling the channel-compensated reception symbol;
a walsh demodulator for despreading the descrambled reception symbol through walsh demodulation;
a demodulator for demodulating the despread reception symbol through soft decision;
a channel deinterleaver for channel-deinterleaving the demodulated reception bit data; and
a MAP decoder for outputting a reception information bit by decoding the channel-deinterleaved bit data.

11. The apparatus of claim 8, wherein the transmitter includes:
a MCS level selector for selecting a MCS level according to the forward channel state information feedback by the receiver;
turbo encoder for turbo-coding a transmit information bit according to the selected MCS level;
a channel interleaver for channel-interleaving the coded information bit according to the selected MCS level;
a modulator for modulating the channel-interleaved information bit according to the MCS level through constellation mapping; and
an antenna selector for selecting an optimum transmit antenna among plural transmit antennas according to the feedback antenna selection information and transmitting the modulated transmit symbol to the selected transmit antenna.

12. The apparatus of claim 11, wherein the transmitter further includes:
a walsh modulator for spreading the modulated transmit symbol by using walsh function; and
a scrambler for scrambling the spread transmit symbol and outputting it to the antenna selector.

13. The apparatus of claim 11, wherein the MCS level selector can be included in not the transmitter but the receiver.

14. The apparatus of claim 8, wherein the receiver is arranged in a mobile terminal, and the transmitter is arranged in a base station.

15. A transmit diversity method for a mobile communication system, comprising:
estimating a forward channel state by decoding a reception signal received through one reception antenna by transmit antennas;
selecting coding rate and modulation method of a forward channel according to the estimated forward channel state;
coding and modulating a transmit data according to the selected coding rate and modulation method of the forward channel; and
transmitting the transmit data through plural transmit antennas by a STTD or STD method.

16. The method of claim 15, further comprising:
demodulating the decoded reception signal;
channel-deinterleaving the demodulated reception data; and
MAP-decoding the channel-deinterleaved reception data.

17. The method of claim 15, wherein the transmitting step by the STTD method includes the sub-steps of:
STTD-coding the transmit data so as to be transmitted through paths orthogonal to each other in temporal spatial regions;
spreading the STTD-coded transmit data by transmit antennas; and
scrambling the transmit data and transmitting it to each transmit antenna.

18. The method of claim 17, wherein the decoding includes:
receiving a transmit signal transmitted through two orthogonal paths with one reception antenna and averaging signals decoded by transmit antennas in temporal and spatial regions.

19. The method of claim 15, wherein the transmitting step by the STD method includes the sub-steps of:
selecting an optimum transmit antenna among the estimated forward channel states; and
transmitting the transmit data to the selected transmit antenna.
